(19) United States
(12) Patent Application Publication
(10) Pub. No.: US 2017/0324121 A1
(43) Pub. Date: Nov. 9, 2017

(54) SYSTEM AND METHOD FOR IDENTIFYING BATTERIES

(71) Applicant: Tricopian, LLC, Del Mar, CA (US)

(72) Inventor: Chi W. Yau, Escondido, CA (US)

(21) Appl. No.: 15/656,355

(22) Filed: Jul. 21, 2017

Related U.S. Application Data
(63) Continuation of application No. 14/398,847, filed on Nov. 4, 2014, now abandoned.
(60) Provisional application No. 61/643,026, filed on May 4, 2012.

(51) Int. Cl. H01M 10/48; H01M 2/02; H01M 10/42; G01R 31/36; H01M 2/10

(52) U.S. Cl. CPC H01M 10/48; H01M 10/4221; H01M 2/0267; G01R 31/3662; H01M 10/425; H01M 2/105; H01M 2010/4278; H01M 2220/30

(57) ABSTRACT

Various embodiments of a system and method for identifying a battery are generally described. In some embodiments, the battery identification system comprises a battery with a portion of exposed can and electrodes configured to measure an electrical property of the battery. In some embodiments, the measured electrical property is the voltage between the can and a first terminal of the battery. In some embodiments, a battery is identified based on an identification mark such as a ringed barcode or two-dimensional barcode.

### CROSS REFERENCE TO RELATED APPLICATIONS

The current application is a continuation of U.S. application Ser. No. 14/398,847, filed Nov. 4, 2014, which claims priority to and the benefit of International application PCT/US2013/031667, filed Mar. 14, 2013, which, in turn, claims priority to and the benefit of U.S. Provisional Application No. 61/643,026, filed May 4, 2012, the entire contents of which is herein incorporated by reference.

### BACKGROUND

### Field of the Invention

This relates to the field of batteries, and particularly to the field of identifying rechargeable or reusable batteries.

### Description of the Related Art

Batteries power a variety of devices. As more devices become battery powered, consumer demand for batteries increases. This results in the manufacture and disposal of ever greater numbers of batteries, which can include precious metals or toxic materials such as mercury, cadmium, or lead. Some people have begun using rechargeable batteries to save money and to minimize battery waste.

### SUMMARY

Some embodiments relate a system for identifying a battery. The battery identification system can include a battery comprising a can, a first terminal, a second terminal, and an insulating jacket disposed on the can, the insulating jacket comprising a computer readable identification mark; and an identification unit configured to identify the battery.

In some embodiments, the identification mark is an exposed portion of the can.

In some embodiments, the exposed portion of the can is a band extending circumferentially around the battery, and wherein the band is located near the first terminal or near the second terminal.

In some embodiments, the band is from about 1/16 inch to about ½ inch wide.

In some embodiments, the identification unit is configured to sense electrical properties at the first terminal, the second terminal, and the exposed portion of the can.

In some embodiments, the identification mark is mark is selected from the group consisting of: a one-dimensional barcode, a two-dimensional barcode, a RFID tag, and an ultraviolet fluorescent marking.

In some embodiments, the barcode is disposed continuously around the outer perimeter of the can.

In some embodiments, the identification mark is disposed on a first or second end of the battery.

In some embodiments, the identification mark comprises concentric stripes.

In some embodiments, the identification mark is a two-dimensional barcode or an ultraviolet fluorescent marking.

Some embodiments include system for identifying a battery comprising a battery comprising a can, a first terminal, a second terminal, and an electrically insulating jacket disposed on the can such that a portion of the can is exposed; a first electrode configured to contact a first area of the battery, a second electrode configured to contact a second area of the can; an identification unit comprising a sensing device, wherein the sensing device is in electrical contact with the first electrode and the second electrode, wherein the sensing device is configured to measure a property of the battery sensed across the first and second electrodes and to communicate the measured property to the identification unit; and wherein the identification unit is configured to identify the battery based on the measured property.

In some embodiments, the first area of the battery corresponds to the first terminal and the second area of the battery corresponds to the second terminal.

In some embodiments, the first area of the battery corresponds to the first terminal and the second area of the battery corresponds to the exposed portion of the can.

In some embodiments, the sensing device senses voltage.

In some embodiments, the sensing device senses resistance.

In some embodiments, the sensing device senses current.

In some embodiments, the sensing device senses voltage, resistance, and current.

In some embodiments, the identification unit positively identifies the battery based on the sensed voltage, the sensed resistance, and/or the sensed current.

In some embodiments, a third electrode is configured to contact the second terminal.

In some embodiments, the identification unit is configured to positively identify the battery when the voltage measured across the first electrode and the second electrode is a non-zero voltage.

In some embodiments, the identification unit is configured to positively identify the battery when the voltage measured across the first electrode and the second electrode is zero or nearly zero.

In some embodiments, the identification unit is configured to positively identify the battery when the resistance measured across the first electrode and the second electrode is greater than about zero ohms.

In some embodiments, the identification unit is configured to positively identify the battery when the resistance measured across the first electrode and the second electrode is zero or nearly zero.

In some embodiments, the identification unit is configured to positively identify a battery based on a voltage 2-point signature.

In some embodiments, the identification unit is configured to positively identify a battery based on a resistance 2-point signature.

In some embodiments, the identification unit is configured to positively identify a battery based on a current 2-point signature.

In some embodiments, the exposed portion of the can comprises a plurality of exposed portions disposed in a pattern on the electrically insulating jacket, and wherein the system further comprises a battery rotation mechanism and a plurality of electrodes configured to contact the plurality of exposed portions of the electrically insulating jacket as the battery rotating mechanism rotates the battery.

Some embodiments include a method of identifying a battery comprising: receiving a target battery, the battery comprising: a first terminal, a second terminal, a can, and

a jacket disposed on a can wherein the jacket at least partially exposes the can; contacting a first area of the battery with a first electrode; contacting a second area battery with a second electrode; measuring an electrical property of the battery using the first and second electrodes; and identifying the battery based on the measured electrical property of the battery.

In some embodiments, the first area corresponds to the first terminal and the second area corresponds to the exposed band.

In some embodiments, the method may comprise contacting the second terminal with a third electrode; measuring the electrical property of the battery using the second and third electrodes; and identifying the battery based on the measured electrical property of the battery.

In some embodiments, measuring the electrical property comprises measuring voltage.

In some embodiments, measuring the electrical property comprises measuring resistance.

In some embodiments, measuring the electrical property comprises measuring current.

In some embodiments, measuring the electrical property comprises measuring voltage, resistance, and current.

In some embodiments, identifying the battery comprises positively identifying the battery when the measured voltage between the first electrode and the second electrode is a non-zero voltage.

In some embodiments, identifying the battery comprises positively identifying the battery when the measured voltage between the first electrode and the second electrode is zero or nearly zero.

In some embodiments, identifying the battery comprises positively identifying the battery when the measured resistance between the first electrode and the second electrode is greater than about zero ohms.

In some embodiments, identifying the battery comprises positively identifying the battery when the measured resistance between the first electrode and the second electrode is zero or nearly zero.

In some embodiments, identifying the battery comprises positively identifying a battery based on a voltage 2-point signature.

In some embodiments, identifying the battery comprises positively identifying a battery based on a resistance 2-point signature.

In some embodiments, identifying the battery comprises positively identifying a battery based on a current 2-point signature.

The foregoing is a summary and thus contains, by necessity, simplifications, generalization, and omissions of detail; consequently, those skilled in the art will appreciate that the summary is illustrative only and is not intended to be in any way limiting. Other aspects, features, and advantages of the devices and/or processes and/or other subject matter described herein will become apparent in the teachings set forth herein. The summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

### BRIEF DESCRIPTION OF THE DRAWINGS

FIG. 1 depicts a side view of an embodiment of a battery having an exposed band.

FIG. 2 depicts a side view of an embodiment of a battery having electrical connections to a sensing device and an exposed end.

FIG. 3 depicts an embodiment of a battery having a rotation-invariant identification barcode in a mid-position.

FIG. 4 depicts an embodiment of a battery having a rotation-invariant barcode in a terminal position.

FIG. 5A depicts an end view of an embodiment of a battery having visually identifiable concentric rings.

FIG. 5B depicts an end view of an embodiment of a battery having a radial barcode.

FIG. 5C depicts an end view of an embodiment of a battery having a quick-recognition code and a high capacity color code.

FIG. 5D depicts an end view of an embodiment of a battery having a radial QR-type code.

FIG. 6 depicts an embodiment of an insulating jacket with a plurality of areas of the can exposed.

FIG. 7 illustrates an embodiment of a process for identifying a battery.

FIG. 8 illustrates an embodiment of a process for identifying a battery using electrical properties.

FIG. 9 illustrates a process for identifying a battery using a visual identification feature.

FIG. 10 is a cutaway view of an embodiment of a rechargeable power unit.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description and drawings are not meant to be limiting. Other embodiments may be utilized, and other changes may be made, without departing from the spirit or scope of the subject matter presented here. It will be readily understood that the aspects of the present disclosure, as generally described herein, and illustrated in the Figures, can be arranged, substituted, combined, and designed in a wide variety of different configurations, all of which are explicitly contemplated and make part of this disclosure.

Embodiments of a system and method for identifying batteries are disclosed. Although certain embodiments of the present invention are shown and described in detail, it should be understood that various changes and modifications may be made without departing from the scope of the appended claims. The scope of the present application is in no way limited to the number of constituting components, the materials thereof, the quantities thereof, the relative arrangement thereof, etc.

The term rotation-variant used in reference to identification marks or features on a battery means a feature or mark or symbol that may appear different depending on the orientation of the battery about an axis. For example, a logo, a word, or other similar identification mark may appear different when viewed from different perspectives, and therefore is rotation-variant. The term rotation-invariant used in reference to identification marks or features on a battery means a feature, mark, or symbol that appears the same regardless of the orientation of a battery about an axis or regardless of the point of view of a sensing or identification unit. For example, a stripe, line, barcode, or symbol which encompasses the entire circumference or outer perimeter of a battery and is uniform over the circumference or outer perimeter is rotation-invariant. For example, a barcode may comprise a bar or set of bars which completely encircle or circumscribe the battery, and appear the same regardless of the orientation of the battery when rotated about an axis. However, a barcode may also be rotation-variant, depending on the orientation of its bars, or if it does not encompass the entire circumference or outer perimeter of the battery. The term rotation-agnostic used in reference to identification marks or features on a battery means a feature or mark that may appear different depending on the orientation of the battery about an axis, but can nonetheless be used to identify the battery, regardless of the battery orientation. For example, a mark, symbol, or barcode on an end of a battery may appear different as a battery rotates about an axis, but can still be used to positively identify a battery regardless of orientation. A rotation-agnostic mark may be, for example, a radial bar code, a QR code, a high capacity color barcode, an Aztec code, or other one or two-dimensional barcode, an radio frequency identification (RFID) tag, a marking configured to fluoresce under ultraviolet light, or other marking.

For ease of description and illustration, cylindrical batteries such as AAA, AA, C and D, batteries are used as examples for describing the features of the present disclosure. However, one of skill in the art will recognize that batteries of many shapes and sizes, such as 9V, prismatic batteries, or coin-shaped batteries may be comprise the features described herein without departing from the scope of the present disclosure. Also, it is contemplated that some embodiments may not include all of the recited materials, thus sub-combinations of the listed materials are contemplated.

In some embodiments, a battery may be identifiable based a computer readable identification mark upon recognition of a rotation-variant mark, a rotation-invariant mark, a rotation-agnostic mark, a symbol, electrical characteristics, or other features, or any combination of the foregoing. For example, in some embodiments, a battery may be identifiable based on a rotation-invariant feature, such as a barcode uniformly encompassing the outer perimeter of a battery each of whose bars circumferentially extend around the outer perimeter of the battery, or a set of concentric stripes, circles, or colors on a terminal end of a battery. In some embodiments, a battery may be identifiable based on its electrical characteristics, such as terminal-can voltage, internal resistance, impedance, or similar property. A terminal-can voltage, as used herein, may mean the voltage between any battery terminal and the can of the battery.

Embodiments of the battery identification system may comprise a battery with identification characteristics and a sensing unit capable of recognizing the battery based on the identification characteristics. In some embodiments, the battery identification system is used in an identification apparatus such as battery vending machine, battery exchange machine, or other battery receiving apparatus such as that disclosed in U.S. Patent Application Ser. No. 61/560,672, hereby incorporated by reference in its entirety. In some embodiments, the battery vending machine or battery exchange machine may identify batteries inserted into a test port or receiving port on the machine as being compatible with the machine, being acceptable to the machine, belonging to the machine, or being owned and distributed by the owner or distributor of the battery vending machine, battery exchange machine, or other battery receiving apparatus. An incompatible battery inserted into a battery vending machine or battery exchange machine may interfere with proper operation of the machine, may adversely affect the charging system of the machine, or otherwise cause difficulty. In some embodiments, the owner/operator of a proprietary battery vending machine or battery exchange machine may wish to only exchange proprietary batteries the owner/operator has previously provided. In order to ensure that only previously provided batteries are accepted or exchanged in the battery machine, the machine may have some system for identifying the battery inserted.

Batteries such as AAA, AA, C, D, or 9V generally have insulating jackets covering the battery can. Advantageously, this insulating jacket provides an area for a battery manufacturer to mark a battery and advertise its brand, provide product details, and/or display any other desired information. The insulating jacket also provides for electrical safety by preventing inadvertent contact with the battery can, and prevents inadvertent discharge of the battery if an electrical circuit were inadvertently established with a battery terminal and the can. The can of the battery is generally in electrical contact with either the positive or negative terminal of the battery. As used herein, the positive terminal of a battery is the terminal with a positive polarity in relation to ground, and the negative terminal of a battery is the terminal with a negative polarity in relation to ground. In non-rechargeable, disposable, carbon-zinc, or alkaline batteries, the positive terminal of the battery is usually in direct electrical contact with the battery can, and the can is electrically isolated from the negative terminal, or, in other words, is separated from the negative terminal by the cell or cells within the battery. Thus, a voltage measurement between the can and the positive terminal of a healthy battery will generally yield a measurement of about zero volts. Similarly, a voltage taken between the can and the negative terminal of a healthy battery will generally yield a non-zero negative voltage. Where a terminal of a battery is in direct electrical contact with the can, the voltage across the two should be zero and the resistance should similarly be zero. In some cases, however, the voltage or resistance may not be precisely zero, but nearly zero, based on the quality of connection between the measuring device and the terminals and can, the internal resistance of the measuring device, or other minor variations.

In some embodiments of rechargeable, reusable batteries, such as nickel metal hydride (NiMH), nickel cadmium (NiCd), or lithium ion, the negative terminal of the battery is generally in direct electrical contact with the can and the positive terminal is electrically isolated from the can, or in other words, is separated from the can by the cell or cells within the battery. Thus, a voltage measurement taken between the can and the positive terminal of a healthy rechargeable battery will yield a non-zero positive voltage. Similarly, a voltage measurement taken between the can and the negative terminal will yield a voltage of about 0V. In some embodiments of disposable, alkaline batteries, the voltage measurement between the can and the positive terminal will read nearly zero or zero. For example, alkaline and nickel metal hydride batteries have different terminal-can voltage properties. Whereas most rechargeable batteries are nickel-cadmium or nickel metal hydride, and most disposable batteries are alkaline, this property can be used to distinguish between most disposable and rechargeable batteries. For example, Lithium ion and lithium polymer batteries have a different charged voltage (e.g. 3.6 to 3.7 volts) and usually have a different general shape than the NiCd and NiMH, alkaline, and carbon zinc batteries. Terminal-can voltage may also be used to distinguish between different types of disposable batteries or different types of rechargeable batteries. In some embodiments, a battery can be identified as either a disposable battery or a rechargeable battery based on the terminal-can voltage measurement. In some embodiments, this property may be used to distinguish between varying types of rechargeable batteries, e.g., nickel metal hydride and alkaline rechargeable batteries.

Because of the electrical arrangement of the can and the terminals in disposable alkaline batteries and some rechargeable batteries, impedance or resistance between the can and a terminal may be measured and used to distinguish between types of batteries. For example, alkaline and nickel metal hydride batteries have different terminal-can resistance properties. Whereas most rechargeable batteries are NiCd or NiMH, and most disposable batteries are alkaline or carbon zinc, this property can be used to distinguish between most disposable and rechargeable batteries. This property may also be used to distinguish between different types of disposable batteries or different types of rechargeable batteries. As used herein, because the batteries described generally produce direct current (DC), the terms impedance and resistance may be used interchangeably.

In non-rechargeable, disposable, alkaline batteries, the positive terminal of the battery is usually in direct electrical contact with the battery can, and the can is electrically isolated from the negative terminal, or, in other words, is separated from the negative terminal by the cell or cells within the battery. Thus, a resistance measurement between the can and the positive terminal of a healthy, non-rechargeable battery will generally be zero or nearly zero. However, resistance taken between the can and the negative terminal of a healthy battery will generally yield a high resistance, for example, greater than about 90 mΩ. A voltage taken between the positive terminal of a healthy non-rechargeable battery and the can will yield zero or nearly zero volts. A voltage taken between the negative terminal of a healthy, non-rechargeable battery will yield a non-zero, negative voltage.

In rechargeable, reusable batteries, the negative terminal of the battery is generally in direct electrical contact with the can and the positive terminal is electrically isolated from the can, or in other words, is separated from the can by the cell or cells within the battery. Thus, a resistance measurement taken between the can and the positive terminal of a healthy rechargeable battery will be a low, non-zero value, for example, less than about 90 mΩ. However, a resistance measurement taken between the can and the negative terminal of a healthy, rechargeable battery will yield zero or nearly zero resistance. A voltage measurement taken between the positive terminal of a healthy, rechargeable battery and the can will yield a non-zero, positive voltage. Similarly, a voltage measurement taken between the negative terminal of a healthy, rechargeable battery and the can will yield zero or nearly zero volts. Because of the voltage and resistance characteristics of different types of batteries, a battery can be identified as either a disposable battery or a rechargeable battery based on the terminal-can resistance and/or voltage measurements.

Similar to the above properties, voltage and resistance, in some embodiments, a measured or sensed current value may be used to identify rechargeable and non-rechargeable batteries.

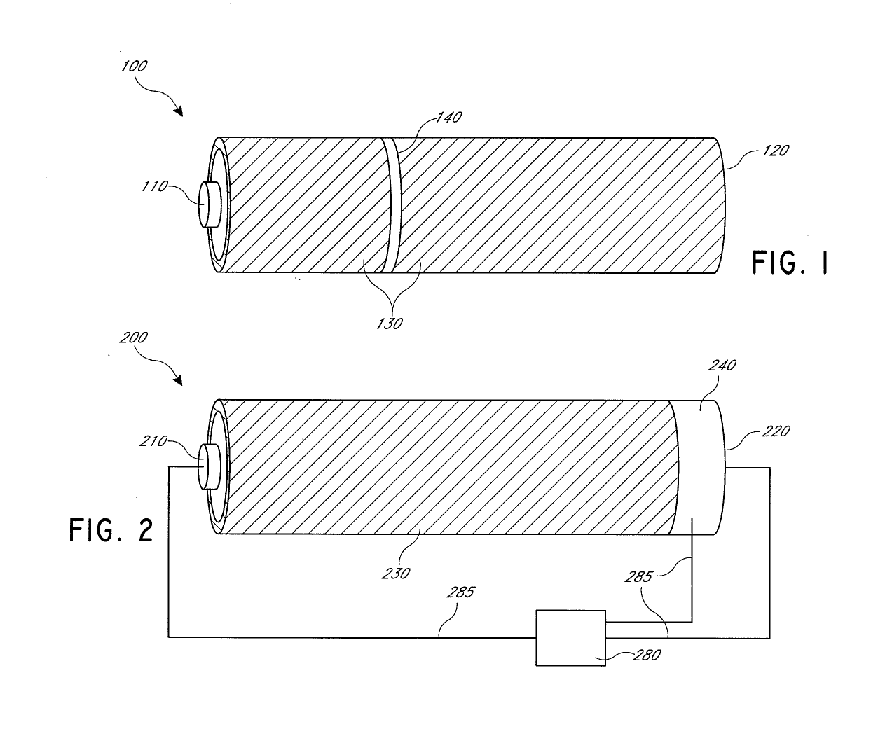

Referring to FIG. 1, battery 100 comprises a first terminal 110, a second terminal 120, a can (not shown), and an insulating jacket 130 which substantially covers the battery can. Insulating jacket is formed with an exposed band 140. Exposed band 140 is an exposed portion of the can which is not covered by insulating jacket 130. The exposed band 140 can comprise a variety of widths, sizes, shapes, and locations. In some embodiments, the exposed band 140 circumferentially extends around all or a portion of the can. Exposed band 140 may have many varying configurations. For example, exposed band may be disposed in the center of the battery can. In some embodiments, exposed band 140 may be disposed away from the center of the can, or near a terminal end of the battery. In some embodiments the exposed band may be ¼ inch wide. In some embodiments, the exposed band 140 may be less than ¼ inch wide, or greater than ¼ inch wide. In some embodiments, exposed band may be 1/16 inch, ⅛ inch, 5/16 inch, ⅜ inch, 7/16 inch, ½ inch, 9/16 inch, ⅝ inch, 11/16 inch, ¾ inch, 13/16 inch, ⅞ inch, 15/16, inch, 1 inch, 1¼ inches, 1½ inches, 1¾ inches, or any dimension below, between, or above the recited values. In some embodiments, the insulating jacket 130 can comprise one or several exposed bands 140. In some embodiments, the insulating jacket 130 can comprise a plurality of exposed bands 140 located at unique radial and/or axial positions on the battery 100. Exposed band 140 provides access for electrical contact with the battery can so electrical measurements may be taken between the battery can and either first terminal 110 or second terminal 120. In some embodiments, exposed band 140 may be disposed at a position away from the ends of battery 100. As depicted in FIG. 1, exposed band may be located nearer to one terminal than the other. Where there is a plurality of exposed bands 140, their locations can be used to optically or electro-mechanically ascertain the orientation of positive and negative terminals, and to assist in mechanically reorienting the battery, if necessary, before testing or charging.

In some embodiments, a battery maybe identified by taking a terminal-terminal voltage or resistance. For example, in a healthy, charged alkaline battery, the voltage measurement taken between first terminal and second terminal 120 may be about 1.5 volts, and the terminal-terminal resistance may be greater than about 90 mΩ. In a healthy, charged NiMH or rechargeable battery the terminal-terminal voltage may be about 1.2 volts and the terminal-terminal resistance may be less than about 90 mΩ.

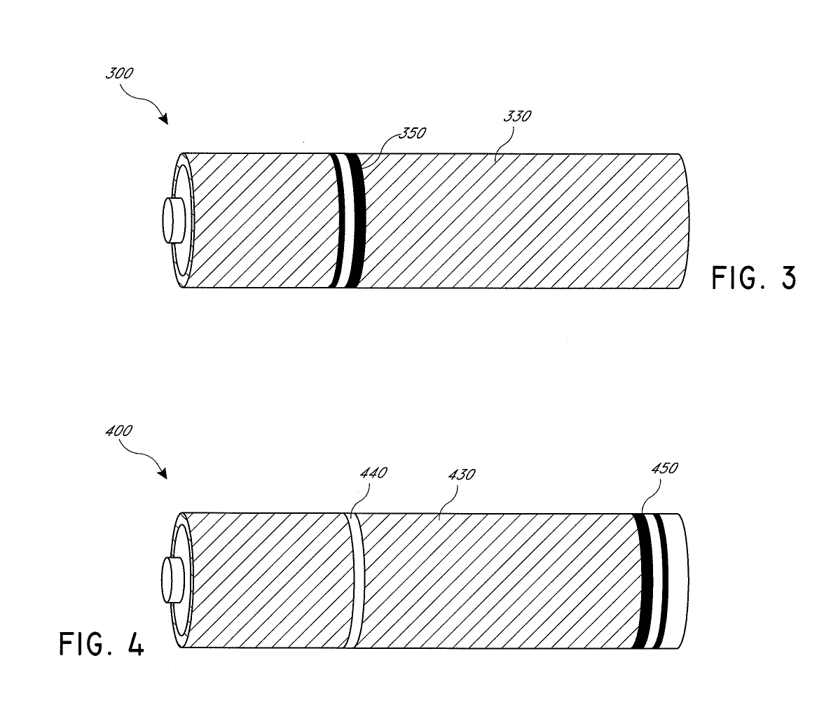

FIG. 2 depicts a side view of an embodiment of a battery 200 having electrical connections to a battery meter 280 and an exposed end. Battery 200 comprises an exposed band located at or near the end of battery 200. Battery 200 comprises insulating jacket 230, a first terminal 210 in electrical contact with battery meter 280 via one of electrical connections 285, a second terminal 220 in electrical contact with battery meter 280 via another of electrical connections 285, and exposed band 140 in electrical contact with battery meter 280 via a third one of electrical connections 285. In some embodiments, a battery vending machine or battery exchange machine may comprise battery meter 280 and electrical connections 285. When battery 200 is inserted into a battery vending machine or exchange machine, the vending or exchange machine may receive the battery into a test port (not shown) to hold battery in electrical contact with electrical connections 285 and therefore battery meter 280.

Battery test port may be shaped or otherwise configured to accept batteries in a single direction. For example, the test port may have a detent portion on one end sized to receive the raised portion of the first terminal 210. In some embodiments, exposed band 140, or 240 may be disposed at a location along the length of a battery such which is not equidistant from both the positive terminal 210 and negative terminal 220. For example, as depicted in FIG. 1, exposed band 140 is not equidistant from positive terminal 110 and negative terminal 120. When a battery is placed into a test port with the proper orientation, the electrical connection 285 configured to contact the exposed band 140, 240, is in electrical contact with the can of battery 100, 200. If a battery is inserted with improper orientation, the one of electrical connections 285 configured to contact exposed band 140, 240 is not in electrical contact with the can of battery 100, 200. This arrangement provides for rejecting batteries which are improperly inserted in to the test port. If a battery is inserted with the improper orientation, the electrical connection configured to contact positive terminal 210 may actually be in electrical contact with the one of electrical connections 285 configured to contact negative terminal 220, and vice versa. Thus, the voltage or resistance measurements may improperly positively identify a battery. By disposing exposed band 140, 240 at a position not equidistant from positive terminal 110, 210, and negative terminal 120, 220, a battery which is improperly inserted will read zero or near zero volts between either terminal and exposed band 140, 240, and high resistance between either terminal and exposed band 140, 240. In this case, the battery meter will not positively identify any battery which is incorrectly inserted into the test port. If the battery meter reads this particular circumstance, the battery vending machine, battery exchange machine, or other battery receiving device may provide an indication that a battery is improperly inserted into the test port.

In some embodiments, the battery vending machine, battery exchange machine, or other battery receiving device may have 2 pairs of electrical connections so that the machine can perform identification tests regardless of the orientation. Based on which pairs of connections are activated may indicate in which orientation the battery in disposed within a test port.

In some embodiments, if a battery is inserted with the incorrect orientation, the battery vending machine, battery exchange machine, or other battery receiving apparatus may be configured to re-orient the battery using a mechanical element. If a battery is incorrectly inserted, the test port within the machine may rotate as needed to ensure the proper connections are made to battery meter 280. In some embodiments, the battery vending machine, battery exchange machine, or other battery receiving apparatus may comprise a mechanical device which removes the battery, rotates the battery for the correct orientation, and replaces the battery in the test slot.

In some embodiments, the battery vending machine, battery exchange machine, or other battery receiving apparatus may detect an improperly inserted battery, and may reconfigure the electrical connections 285 so they align with the battery in the improper orientation. In some embodiments, battery meter 280 may detect the orientation of the battery, and adjust the identification parameters accordingly. For example, if a battery is inserted in an orientation opposite the expected orientation, battery meter 280 may sense the improper orientation or may receive a signal that the orientation is improper. The battery meter 280 may interpret the voltage or resistance 2-point signature as required to positively identify the battery.

By way of example only, as described above, first terminal 210 may be referred to as the positive terminal, and second terminal 220 may be referred to as the negative terminal. The positive terminal is assumed to have a positive polarity and the negative terminal is assumed to have a negative polarity. A person skilled in the art will understand that the designation of first terminal 210 as the positive terminal and second terminal 220 as the negative terminal is for ease of discussion only. In practice, the polarity of the voltage at first terminal 210 and second terminal 220 may vary. In some embodiments, when battery 200 is received into a test port, which may be located on or in a battery vending machine or battery exchange machine, battery meter 280 may measure the voltage between first terminal 210 and exposed band 240. In some embodiments, battery meter 280 may measure the resistance or impedance between first terminal 210 and exposed band 240. In some embodiments, battery meter 280 may measure both voltage and resistance between first terminal 210 and exposed band 240.

In some embodiments, battery meter 280 may measure the voltage between second terminal 220 and exposed band 240. In some embodiments, battery meter 280 may measure the resistance or impedance between second terminal 220 and exposed band 240. In some embodiments, battery meter 280 may measure both voltage and resistance between second terminal 220 and exposed band 240. In some embodiments, battery meter 280 may measure voltage between both the first terminal 210 and exposed band 240 and the second terminal and exposed band 240. In some embodiments, battery meter 280 may measure resistance between both the first terminal 210 and exposed band 240 and the second terminal and exposed band 240. The measurement of a property between both the first terminal 220 and exposed band and second terminal and exposed band 240 may be referred to as the “2-point signature” of a battery. If the property of the battery measured between both the first terminal 210 and exposed band 240 and second terminal 220 and exposed band 240 is voltage, this may be referred to as the “voltage 2-point signature.” If the property is resistance, this may be referred to as the “resistance 2-point signature.” If the property is current, this may be referred to as the “current 2-point signature.”

By evaluating the voltage 2-point signature and the resistance 2-point signature, a battery can be positively identified. In some embodiments, a battery may be positively identified if it has the following voltage 2-point signature: the voltage between first terminal 210 (positive terminal) to exposed band 240 voltage is a non-zero positive voltage and second terminal 220 (negative terminal) to exposed band 240 voltage is about zero. A healthy alkaline battery 200 may be rejected if the voltage 2-point signature is as follows: first terminal 210 (positive terminal) to exposed band 240 voltage is zero or nearly zero and second terminal 220 (negative terminal) to exposed band 240 voltage is a non-zero negative voltage.

In some embodiments, a healthy battery 200 may be positively identified if it has the following resistance 2-point signature: the resistance between first terminal 210 (positive terminal) and exposed band 240 is low, for example, less than about 90 mΩ, and the resistance between second terminal 220 (negative terminal) and exposed band 240 is zero or nearly zero. A healthy battery 200 may be rejected if the resistance 2-point signature is as follows: the resistance between first terminal 210 (positive terminal) and exposed band 240 is zero or nearly zero and the resistance between second terminal 220 (negative terminal) and exposed band 240 is high, for example, greater than about 90 mΩ.

In some situations a battery with no exposed band may be presented for identification. In this situation, the electrical connection corresponding to exposed band 240 on battery 200 will be in contact with the battery's insulating jacket. As a result, battery meter 280 will read a zero or nearly zero voltage between both the positive terminal and the electrical connection usually corresponding to the exposed band, and the negative terminal and the electrical connection usually corresponding to the exposed band. Similarly, the resistance measured by battery meter 280 between the same points as described above will be a large value corresponding to that of an open-circuit state. In some embodiments, a battery having these 2-point signatures is rejected.

In addition to the use of the 2-point signature, the use of the exposed band 240 in connection with the battery 200 can provide additional information relating to the battery 200. In some embodiments, for example, the size and/or position of a single exposed band 240 can provide additional information relating to the battery 200, and can comprise, for example, a computer readable code. This information can include, for example, identification of the battery, battery type, battery manufacture information, or any other desired information. In some embodiments, these exposed bands 240 can be uniquely axially and/or radially positioned on the battery 200. In some embodiments, the battery meter 280 can detect the properties of each of the exposed bands 240 located on a battery 200, and these detected properties can be used to determine the information associated with the battery 200.

NiMH batteries may have a higher concentration of magnetic metals, such as nickel, iron, and rare earth elements as compared to standard alkaline cells of the same size. Thus, NiMH batteries may be identified using a magnet to separate NiMH cells from standard alkaline cells. This technique may be employed in a battery vending or exchange machine by measuring the strength of a magnetic field or the effect of a battery on an applied magnetic field. In some embodiments, a NiMH battery may be identified based on its magnetic properties.

In some embodiments, a battery may be identified by a rotation invariant symbol or mark on the insulating jacket. FIG. 3 depicts an embodiment of a battery 300 having a rotation-invariant identification barcode in a mid-position. Battery 300 comprises an insulating jacket 330 comprising a rotation invariant barcode 350. Barcode 350 may be printed on insulating jacket 330, be formed integrally with insulating jacket 330, or otherwise be part of insulating jacket 330. Barcode 350 may be one of many generally known one-dimensional barcode protocols. For example, barcode 350 may use the Pharma code protocol as promulgated in Pharma Code Specifications from RC Electronica, located at www.reclectronica.com. Because a one-dimensional barcode can be configured to entirely, uniformly encompass the outer circumference or perimeter of a battery, the barcode can be read regardless of the rotational position about an axis perpendicular to barcode 350. A pharma code barcode uses from 2 up to 16 bars, each bar being either wide or narrow. The bars encode numbers in binary notation. In some embodiments, battery 300 may have a 2 bar pharma code. Using a pharma code on a battery may be advantageous in that a minimal amount of space on the battery jacket is occupied. In some embodiments, the 2 bar pharma code may advantageously occupy a minimal area of the battery jacket. In some embodiments, a battery may have a pharma code of 3 or more bars. The number encoded in the pharma code may be read by a scanner in a battery vending machine or a battery exchange machine. In some embodiments, all batteries may have the same pharma code and the presence of a pharma code is enough to positively identify a battery. In some embodiments, batteries of different sizes, e.g., A, AA, AAA, C, D, 9V, may have different numbers encoded in pharma code to positively identify a battery, and to allow the battery vending machine, battery exchange machine, or other battery receiving apparatus to track quantity and inventory of batteries taken in and/or dispensed. In some embodiments, each battery may have a unique barcode or symbol used to positively identify and track each battery.

In some embodiments, a battery having a rotation-invariant image may be presented for identification in a battery vending machine or battery exchange machine. Battery 300 may be inserted into a test port, the test port comprising a barcode scanner. If battery 300 had a rotation variant mark or symbol, a barcode scanner in the test port may not be able to read the barcode. A battery 300 comprising rotation-invariant barcode 350 may be identified regardless of its orientation in the test port, because at least a portion of barcode 350 will be readable by a barcode scanner.

In some embodiments, a battery may have more than one identifying characteristic. For example, FIG. 4 depicts a battery 400 comprising an insulating jacket 430, an exposed band 440, and a rotation invariant barcode 450. In some embodiments, a battery vending machine, battery exchange machine, or other battery receiving apparatus may only have the capability to identify a battery based on a rotation invariant mark, symbol, or barcode. In some embodiments a battery vending machine or battery exchange machine may only have the capability to identify a battery based on a 2-point signature. In some embodiments, a battery vending machine, battery exchange machine, or other battery receiving unit may sense a 2-point signature, a rotation-variant mark, and a rotation-invariant mark. A battery having more than one identifying characteristic, such as battery 400, may be used in a battery vending machine or battery exchange machine regardless of the identification system employed by the battery vending machine or the battery exchange terminal.

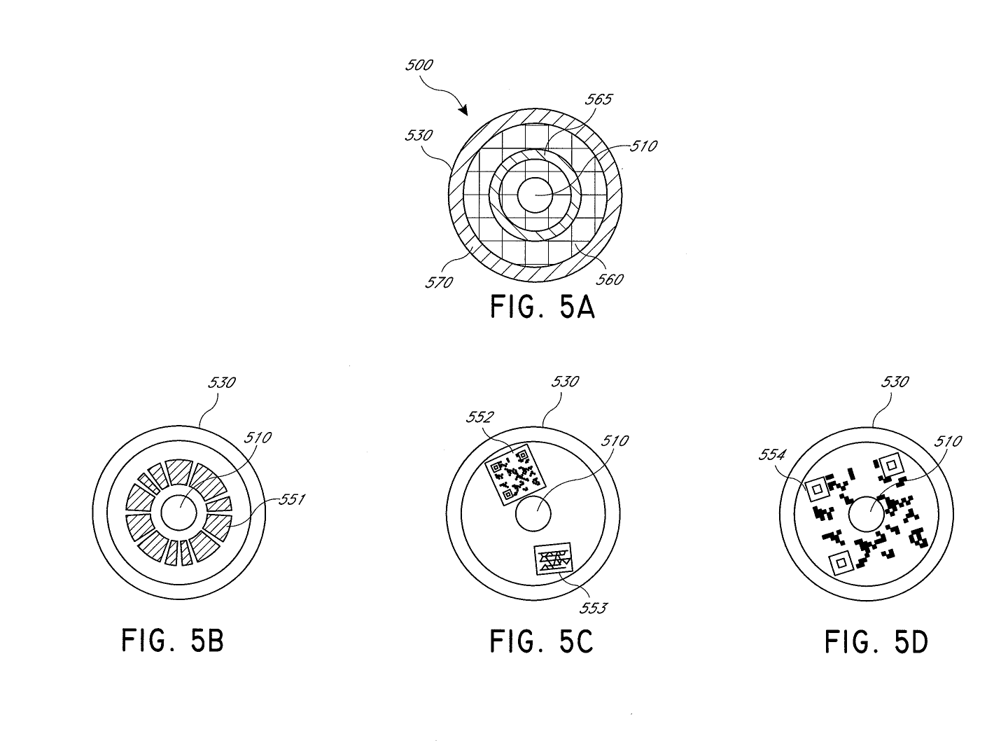

In some embodiments, a battery may have a rotation-invariant, visually identifiable pattern disposed on an end or on a terminal. FIG. 5A depicts an end view of an embodiment of a battery 500 having visually identifiable concentric rings. Battery 500 comprises a first terminal 510, and a first concentric ring 560 and a second concentric ring 565. Insulating jacket 530 comprises an end portion 570. The pattern of concentric rings is visually identifiable. Concentric rings 560 and 565 may comprise a particular color pattern, shading pattern, width pattern, marking pattern (e.g. dotted, dashed, etc. lines), or other visually identifiable pattern. The visually identifiable pattern of concentric rings 560 and 565 may further comprise, end portion 570 of insulating jacket 530. In some embodiments, concentric rings 560 and 565 may be disposed around or near the second terminal 520. In some embodiments, the concentric rings 560 and 565 may be disposed on or around either end or terminal of the battery. In some embodiments, concentric rings 560 and 565 may be disposed on or around both ends and terminals. In some embodiments, battery 500 is presented for identification in an identification apparatus such as a battery vending machine or battery exchange machine. The identification apparatus may comprise a test port and visual scanner, camera, barcode reader or other device configured to visually identify a battery. A database of patterns, images, or symbols which positively identify a battery may be referenced by the identification apparatus. A battery comprising a positively identifiable image contained within the database may be accepted by the identification apparatus, and a battery without a positively identifiable image may be rejected.

FIG. 5B depicts an end view of an embodiment of a battery having a radial barcode. Battery 500, as depicted, has a rotation agnostic radial barcode 551 on an end. Radial barcode has scannable segments which radiate out from the center of positive terminal 510. In some embodiments, the radial barcode may be located on the negative terminal 520. By alternating the width of the segments, a code can be programmed onto the end of each battery. In some embodiments, a unique barcode may be used to encode the type or size of battery, or the origin of the battery. In some embodiments, individual batteries may have their own individual identifiers. By assigning each battery a unique identifier or barcode, the battery vending machine, battery exchange machine or other battery receiving apparatus may be able to identify the account associated with a particular battery and can update or credit account information based on the unique identifier or barcode.

Battery 500 may have a rotation agnostic QR code or other two dimensional code located on an end. FIG. 5C depicts an end view of an embodiment of a battery having a quick-recognition (QR) code 552 and a high capacity color barcode (HCCB) 553. The QR code 552, HCCB 553, or other two-dimensional barcode may appear different depending on the rotation of the battery about an axis, however, the battery vending machine, battery exchange machine, or other battery receiving apparatus is capable of reading and interpreting a two-dimensional barcode regardless of the rotation of the battery about an axis. Thus, the two-dimensional barcode may be rotation agnostic. Each battery may have a unique QR code, high capacity color code, or other two-dimensional code. When a battery is vended or supplied, the battery barcode is associated with the account, transaction, customer, purchaser, user, borrower, or other entity. When the battery is returned to a battery vending machine, battery exchange machine, or other battery receiving apparatus, the battery is identified by its unique code, and the account, transaction, customer, borrower, purchaser, user, or other entity can be accessed and credited or debited based on the particular transaction. In some embodiments, an account holder would not need to input any personal information into the battery exchange machine, battery vending machine, or other battery receiving apparatus in order to identify itself, but the account holder would be identified automatically based on the unique, rotation agnostic code on the end of each battery and its association with an account.

FIG. 5D depicts an end view of an embodiment of a battery having a radial QR-type code. In some embodiments, battery 500 may have a radial QR-type code 554 disposed on an end of the battery. A two dimensional barcode such as the QR-type code 554 depicted may encode battery information and be associated with an account as described elsewhere herein. In some embodiments, QR-type code 554 may be an HCCB or other type of two-dimensional barcode as described elsewhere herein.

In some embodiments, end portion 570 of insulating jacket 530, together with concentric rings 560 and 565 may comprise a circular pharma code pattern. End portion 570 and concentric rings 560 and 565 may vary in width in accordance with a pharma code pattern. A barcode scanner may be configured in a test port of an identification apparatus which reads a portion or all of the circular pharma code and positively identifies or rejects battery 500. The pharma code may be configured as disclosed elsewhere herein.

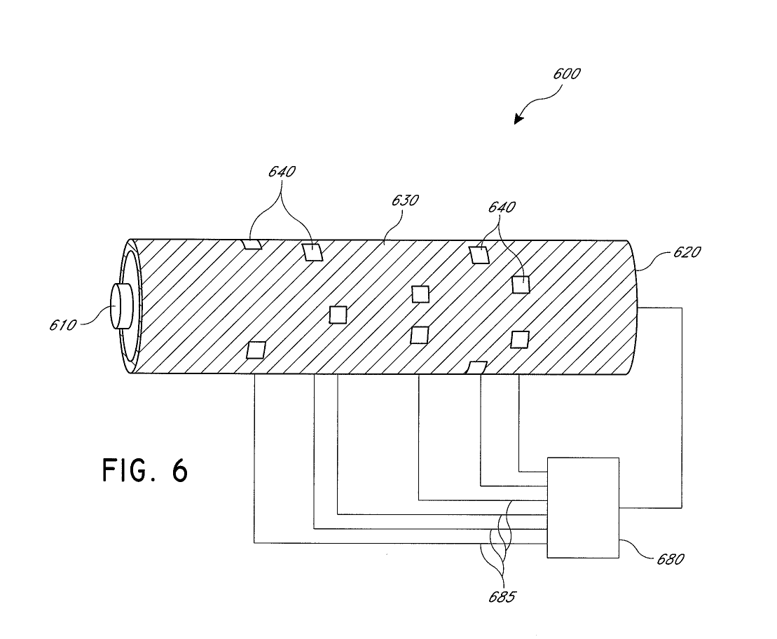

FIG. 6 depicts an embodiment of battery having an insulating jacket with a plurality of areas of the can exposed. In some embodiments, the insulating jacket 630 of battery 600 may comprise a plurality of exposed areas 640. Exposed areas 640 may be disposed around the perimeter of battery 600 in a pattern or specific arrangement. A battery vending machine, battery exchange machine, or other battery receiving apparatus into which battery 600 is inserted may comprise battery meter 680 and a plurality of electrical connections 685. The plurality of electrical connections 685 may be disposed along an edge of the can of battery 600. Battery 600 may rotate along an axis, for example, along the axis running through positive terminal 610 and negative terminal 620. As battery 600 rotates, the plurality of exposed areas 640 rotate, and one or more of the plurality of electrical connections 685 alternately makes contact with one or more of the plurality of exposed areas 640 and insulating jacket 630. As battery 600 rotates and the plurality of electrical connections are alternately or intermittently contacting the battery can via the plurality of exposed areas 640, a specific voltage pattern may be detected by battery meter 680. This specific voltage pattern may comprise a varying, time-dependent pattern of high and low voltages detected at intervals among the plurality of electrical connections. The specific voltage pattern may be used to positively identify battery 600. The specific voltage pattern may encode information. Various patterns may be employed on various batteries to communicate information about the specific battery such as size, type, origin, manufacture date, manufacturing lot number, manufacturing location, or other desired parameter or datum. If the specific voltage pattern positively identifies a battery, the battery vending machine, battery exchange machine, or other battery receiving apparatus may perform steps or take actions as described elsewhere herein.

If a battery is inserted, rotated, and battery meter 680 does not detect a specific voltage pattern, or if the voltage pattern does not correspond to a recognizable voltage pattern, the battery may be rejected. If the battery is rejected, the battery vending machine, battery exchange machine, or other battery receiving apparatus may perform steps or take actions as described elsewhere herein.

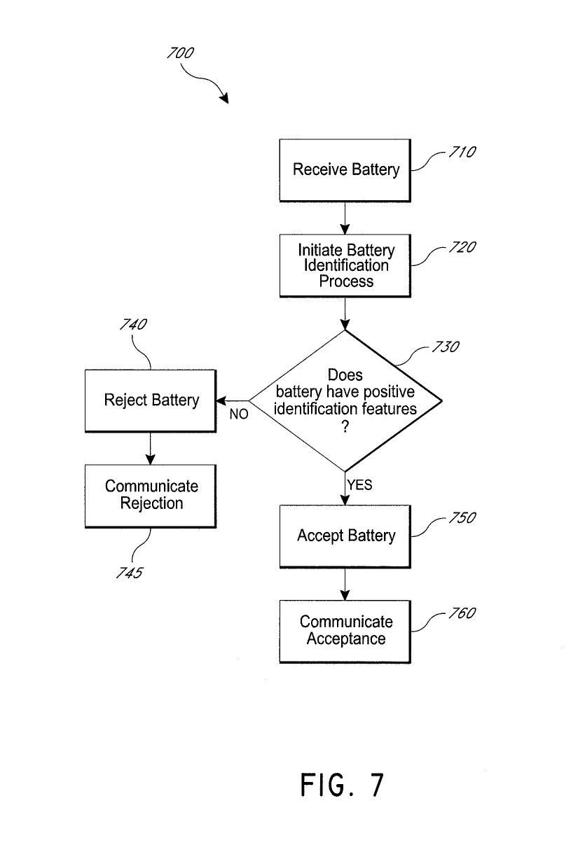

FIG. 7 illustrates an embodiment of a process for identifying a battery. In some embodiments, the illustrated method for evaluating and identifying a battery may be performed automatically by an identification unit contained within a battery vending machine or battery exchange machine, or other battery receiving apparatus. The battery vending machine, battery exchange machine, or other battery receiving apparatus may comprise a test port and control unit configured to perform, carry out, or direct performance of process 700. The control unit may comprise a set of software instructions executable upon an input such as input from user, a remote signal, or from receipt of a battery in the test port.

In block 710, a battery is received into the battery vending machine, battery exchange machine, or other battery receiving apparatus. Once the battery is received, the control unit initiates the battery identification process in block 720. The battery initiation process proceeds to decision state 730. In decision state 730, the control unit directs a determination of whether the battery comprises an identification feature that positively identifies the battery.

If the battery is not positively identified via an identification feature, the battery is rejected in block 740. If a battery is rejected, the control unit may direct placing the rejected battery in a storage area for rejected batteries, or direct placing the battery in a waste receptacle. In some embodiments, a rejected battery may not be taken into the battery vending machine, battery exchange machine or battery receiving apparatus, but may be ejected and returned to the party that placed the battery into the test port.

Following rejection, in block 770, the control unit may direct communicating the rejection. For example, the battery vending machine, battery exchange machine, or other battery receiving apparatus may be directed to generate an indication of rejection. The indication may be an audible or visual indication such as, an audible sound, alarm, or speech. In some embodiments, the visual indication may be a light, a graphical display, or a text stating that the inserted battery has been rejected and no client account has been credited. The control unit may further direct communication of rejection via a wired or wireless network to a central server, other battery receiving apparatuses, or other party.

If the battery is positively identified in decision state 730, in block 750 the battery is accepted. When a battery is accepted, the battery may be placed in an accepted battery storage area or be inserted into an internal charging unit within a battery vending machine or battery exchange machine. Upon accepting a battery, the control unit may direct the battery vending machine, battery exchange machine, or other battery receiving apparatus to generate an indication of acceptance. The indication may be an audible or visual indication. For example, the battery vending machine or battery exchange machine may generate an audible sound, alarm, or speech. In some embodiments, the visual indication may be a light, a graphical display, or a text stating that the inserted battery has been accepted and a client account has been credited. In some embodiments, the control unit may further direct communication of acceptance via a wired or wireless network to a central server, other battery receiving apparatuses, or other party.

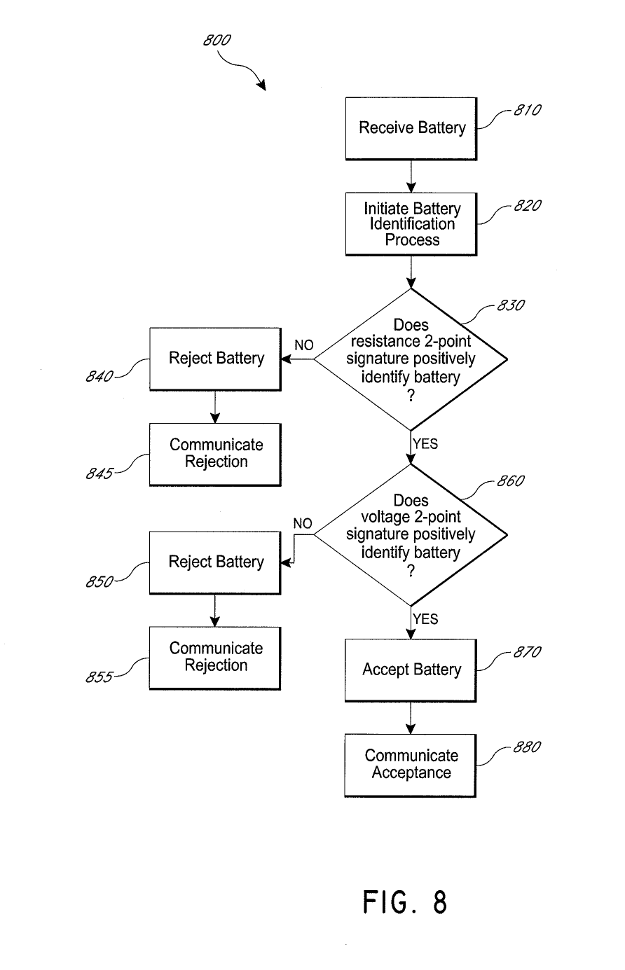

FIG. 8 illustrates an embodiment of a process for identifying a battery using electrical properties. In some embodiments, this method for evaluating and identifying a battery may be performed automatically by an identification unit contained within a battery vending machine or battery exchange machine, or other battery receiving apparatus. The battery vending machine, battery exchange machine, or other battery receiving apparatus may comprise a test port and control unit configured to perform, carry out, or direct performance of process 800. The control unit may comprise a set of software instructions executable upon an input such as input from user, a remote signal, or from receipt of a battery in the test port.

In block 810, a battery is received into the test port, and the battery identification protocol or process is initiated. In block 820, the identification unit initiates a test protocol or battery identification process. Identification unit may comprise a sensing device such as a battery meter as described elsewhere herein.

In decision state 830, the identification unit measures the resistance 2-point signature of a battery in the test port as described elsewhere herein. If the battery is not positively identified, in block 840 the battery is rejected. A battery may not be positively identified if, for example, the resistance 2-point signature does not match with the resistance 2-point signature criteria stored in the control unit or in a database accessible by the control unit. A rejected battery may be discarded, placed in a waste receptacle, or placed in a storage area for later disposal. A battery may be rejected, for example, if the resistance between the positive terminal and the can is zero or near zero or if the resistance between the negative terminal and the can is greater than about 90 mΩ. In some embodiments, the process for identifying a battery may comprise measuring only a single electrical property of a battery, such as only one terminal-can resistance. A battery may be rejected if the measured terminal-can resistance is measured and does not meet the criteria for positive identification.

If a battery is rejected, in block 845 the control unit may direct the battery vending machine, battery exchange machine, or other battery receiving apparatus to generate an indication of rejection. The indication may be an audible or visual indication. For example, the battery vending machine or battery exchange machine may generate an audible sound, alarm, or speech. In some embodiments, the visual indication may be a light, a graphical display, or a text stating that the inserted battery has been rejected and no client account has been credited.

If, in decision state 830 the resistance 2-point signature positively identifies a battery as described elsewhere herein, the process may proceed to decision state 850. In decision state 850, the identification unit measures the voltage 2-point signature of a battery in the test port. If the voltage 2-point signature does not positively identify the battery, the battery may be discarded, placed in a waste receptacle, and/or placed in a storage area for later disposal. A battery may not be positively identified if, for example, the voltage 2-point signature does not match with the voltage 2-point signature criteria stored in the control unit or in a database accessible by the control unit.

In some embodiments, a battery pay be positively identified using a voltage signature based on detecting the voltage of a plurality of exposed areas of the battery can. If, as a battery is rotated in a test port as described elsewhere herein, the plurality of electrical connections detects a voltage signature which is positively identified by the identification unit, the battery is positively identified.

If a battery is not positively identified in decision state 850, the battery is rejected in block 860. A battery may be rejected, for example, if the voltage across the positive terminal and the can is zero or nearly zero volts, and if the voltage across the negative terminal and the can is a non-zero negative voltage. In some embodiments, the process for identifying a battery may comprise measuring only a single electrical property of a battery, such as only one terminal-can voltage. A battery may be rejected if the measured terminal-can voltage is measured and does not meet the criteria for positive identification.

If a battery is positively identified using the voltage 2-point signature, in block 870 the battery is accepted. When a battery is accepted, the battery may be placed in an accepted battery storage area or be inserted into an internal charging unit within a battery vending machine or battery exchange machine. In block 880, upon accepting a battery, the control unit may direct the battery vending machine, battery exchange machine, or other battery receiving apparatus to generate an indication of acceptance. The indication may be an audible or visual indication. For example, the battery vending machine or battery exchange machine may generate an audible sound, alarm, or speech. In some embodiments, the visual indication may be a light, a graphical display, or a text stating that the inserted battery has been accepted and a client account has been credited.

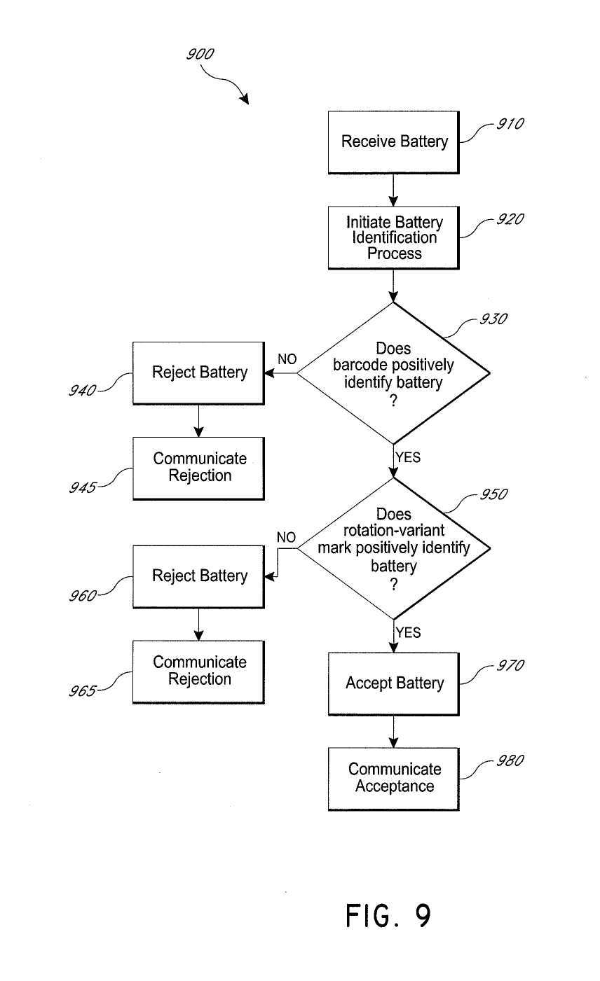

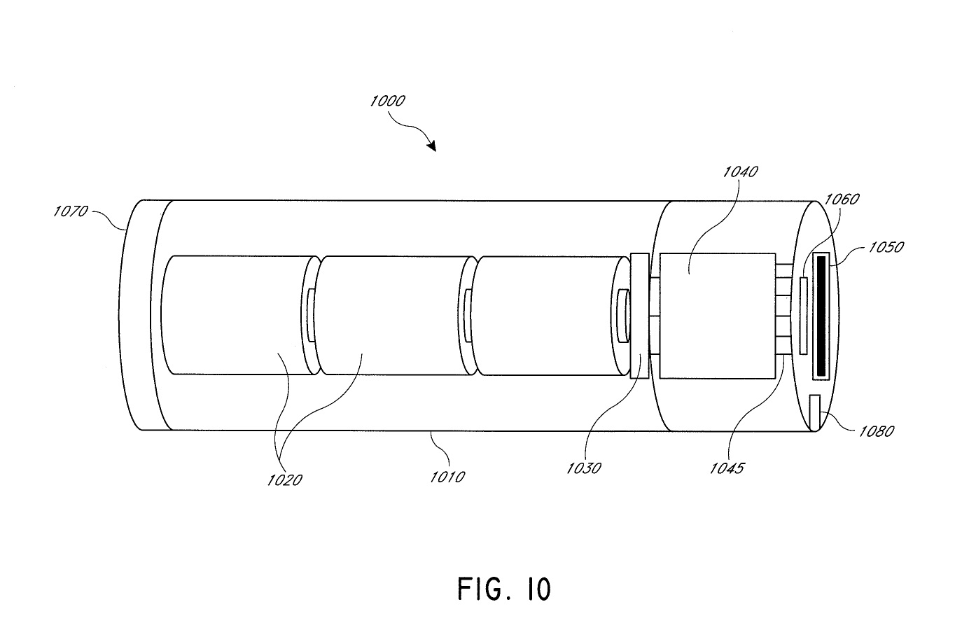

FIG. 9 illustrates a process for identifying a battery using a visual identification feature. In some embodiments, the illustrated method for evaluating and identifying a battery may be performed automatically by a identification unit contained within a battery vending machine or battery exchange machine, or other battery receiving apparatus. The battery vending machine, battery exchange machine, or other battery receiving apparatus may comprise a test port and control unit configured to perform, carry out, or direct performance of process 900. The control unit may comprise a set of software instructions executable upon an input such as input from user, a remote signal, or from receipt of a battery in the test port.

In block 910, a battery is received into the battery vending machine, battery exchange machine, or other battery receiving apparatus. Once the battery is received, the control unit initiates the battery identification process in block 920. The battery initiation process proceeds to decision state 930. Identification unit may comprise a visual scanner capable of identifying and decoding a rotation invariant or rotation variant mark, symbol, or code. The identification unit may comprise a barcode scanner configured to read a pharma code or other one or two dimensional barcode. Identification unit may comprise an optical scanner capable of identifying a rotation-variant, rotation-invariant, or rotation agnostic mark or symbol such as a logo, text, a barcode, number, or other symbol.

In some embodiments, after the battery identification process is initiated, in decision state 930 the identification unit may scan the battery to detect a rotation-invariant mark or symbol, such as a pharma code on the insulating jacket of a battery, or a barcode on one of the terminal ends of the battery. In some embodiments, if the battery does not have a pharma code, or if the detected pharma code does not correspond to a pharma code stored within the control unit or a database to which the control unit has access, then, in block 940, the battery may be rejected. Upon rejection of the battery, the battery vending machine, battery exchange machine or other battery receiving device may communicate rejection in block 945. This may include taking actions described elsewhere herein such as discarding the battery, providing audible or visual indications, and/or communicating over a network with a server or other terminal.

If the battery is positively identified, process 900 proceeds to decision state 950. In decision state 950, the battery may be scanned with an optical scanner capable of recognizing a rotation variant or rotation agnostic identification mark such as a logo, symbol, barcode, word, and other similar mark. Because of the rotation-variant nature of these identification marks, the optical scanner may be configured to recognize a small slice or segment of an identification mark, and extrapolate to determine if the battery has a mark which will positively identify the battery. If the optical scanner fails to positively identify the battery, the battery is rejected in block 960. Upon rejection of the battery, the battery vending machine, battery exchange machine or other battery receiving device may communicate rejection in block 965. This may include taking actions described elsewhere herein such as discarding the battery, providing audible or visual indications, and/or communicating over a network with a server or other terminal.

If the optical scanner positively identifies the battery, the process moves to block 970 and the battery is accepted for return. After accepting the battery, the control unit may direct communicating acceptance of the battery in block 980.

Upon accepting a battery, the control unit may direct the battery vending machine, battery exchange machine, or other battery receiving apparatus to generate an indication of acceptance. The indication may be an audible or visual indication. For example, the battery vending machine or battery exchange machine may generate an audible sound, alarm, or speech. In some embodiments, the visual indication may be a light, a graphical display, or a text stating that the inserted battery has been accepted and a client account has been credited.

In some embodiments the battery vending machine, battery exchange machine, or other battery receiving apparatus may be able to communicate with other units over a wired or wireless network. The battery vending machine, battery exchange machine, or other battery receiving apparatus may communicate to another vending or exchange machine, a central server, or a charging hub that a battery has been received and rejected or that a battery has been accepted and is being charged, available for charging, and/or requesting credit for a client's account. In some embodiments, the communication may comprise the measured electrical characteristics, and/or the barcode identification number of the battery.

It will be understood by one having skill in the art that the steps of process 700, 800, and 900 need not be performed in the order recited, or that all steps need not be performed. In some embodiments, the identification unit may test only the resistance 2-point signature or the voltage 2-point signature. In some embodiments, the identification unit may only scan for a rotation-invariant barcode. The identification process may be performed with a number of permutations, combining the various identification steps in various ways. In some embodiments, various steps of processes 700, 800, and/or 900 may be combined.

FIG. 10 depicts a cutaway view of an embodiment of a rechargeable power unit. The rechargeable power unit 1000 comprises an outer casing 1010, one or more cells 1020, a cell connector 1030, a power input/output module 1040, an output port 1050, and an input port 1060. The outer casing 1010 houses and provides support for the internal components of the rechargeable power unit 1010. The outer casing 1010 may be constructed of an electrically non-conducting material, such as plastic, composite, carbon fiber, cardboard, or other desired material which provides rigidity, maintains its shape, and protects the internal components of the rechargeable power unit 1000. In some embodiments, the outer casing 1010 may comprise a metal or other electrically conductive material which is coated with a rubber, polymer, such as polyvinylchloride, or any other desired electrically isolating material.

One or more cells 1020 are housed within the outer casing 1010. Each of the one or more cells 1020 may be a discrete electrochemical cell, and may be electrically connected to the other of the plurality of cells 1020 either in series or in parallel, as desired. In some embodiments, the one or more cells 1020 may be a single electrochemical cell, or a single cell unit comprising one or more individual but permanently connected electrochemical cells. In some embodiments, the one or more cells 1020 may standard size battery cells, such as AAA, AA, C, D, CR-123, rectangular 9V, and others. The cells may be of a variety of battery chemistries, such as NiMH, NiCd, Li-ion, Li Polymer, and others. The cells 1020 are preferably rechargeable cells, having rechargeable battery chemistry. In some embodiments, the cells 1020 are not rechargeable. In some embodiments, the cells may advantageously be Li-ion 18650 type cells, which have high capacity and low self-discharge rates. In some embodiments, the one or more cells 1020 may have a 1000, 2000, 3000, 4000, 5000 or greater mAh capacity. Although cylindrical cells 1020 are depicted, the cells 1020 may be of any desired form factor, and the outer casing 1010 may be of any geometry, size, or shape, and may be based on the form factor of the cells 1020 housed within.

The one or more cells 1020 are in electrical contact with a cell connector 1030. The cell connector provides an electrical interface between the one or more cells 1020 and the power input/output module 1040. The cell connector 1030 provides contacts or terminals which contact the positive and negative terminals of the one or more cells 1020 to create a circuit for current flow. The cell connector also provides an electrical interface with the power input/output module 1040, and facilitates the transfer of power from the one or more cells 1020 to the power input/output module 1040. Various configurations for the cell connector 1030 may be used, and a person of skill in the art will understand how to facilitate the connection of the one or more cells 1020 to the power input/output module 1040 based on the form factor of the one or more cells 1020.

The power input/output module 1040 is electrically connected to the cell connector 1030 and connection wires 1045, which ultimately connect to the output port 1050 and the input port 1060. The power input/output module 1040 may comprise circuitry configured to transform the voltage and/or current supplied by the cells 1020 into an appropriate output voltage and/or current. The appropriate voltage and/or output current from the output port 1050 may be determined or set according to the intended application for the battery power unit 1000. In some embodiments, the power input/output module 1040 transforms the voltage and/or current values which correspond to a universal serial bus (USB) standard.

The power input/output module 1040 may also be configured to provide a charging voltage and/or current to the one or more cells 1020. Where the one or more cells 1020 are rechargeable, the power input/output module 1040 is configured to receive a charging voltage and/or current from input port 1060, transform the voltage and/or current as required for charging the one or more cells 1020, and transmit the charging voltage and/or current to the one or more cells 1020.

The power input/output module 1040 may also comprise internal circuitry coupled to a cell monitoring circuit capable of performing monitoring functions and storing the monitoring results in an internal memory. For example, the power input/output module 1040 may be configured to calculate amp hours discharged, amp hours charged, number of charge/discharge cycles, total current in or out of the one or more cells 1020. In some embodiments, the internal circuitry of the power input/output module 1040 may be configured to calculate capacity, state of charge, or cell health values, and store the same for later reading by diagnostic equipment, or in a battery vending machine or battery exchange machine. In some embodiments, the power input/output module may comprise a battery monitoring chip similar to the DS2438, manufactured by Dallas Semiconductor.

In some embodiments, the internal memory may be used to store an identification code, such as a serial number, or other unique data. In some embodiments, subscriber or purchaser information, who has requested or ordered or vended the received the rechargeable power unit 100 may be written to the internal memory in the power input/output module 1040.

The output port 1050 receives power from the power input/output module via connection wiring 1045. A person of skill in the art will understand how to configure the connection wiring 1045 to accommodate a variety of styles or types of output ports 1050. The output port 1050 may advantageously be a USB-type port. With a USB-type output port 1050, a user may insert a USB cable into the output port 1050, and may use the battery power unit 1000 to charge virtually any portable electronic device having a USB charging interface. For example, mobile phones, MP3 players, tablet computers, and many other electronic devices are configured for USB charging and can be charged using the battery power unit 1000. In some embodiments, the output port 1050 may be a proprietary port for use with a proprietary connector.

In some embodiments, the rechargeable power unit 1000 may have the form factor of a standard size battery. For example, the outer casing may be sized and shaped like a standard AAA, AA, C, D, and/or 9V cell. The output port 1050 may be a metal concavity or terminal such as exists on the standard AAA, AA, C, D, and 9V cells. In such embodiments, the rechargeable power unit 1000 may be inserted into a slot designed for one of many standard form factor cells.

The input port 1060 may be configured to receive a charging signal sufficient to recharge the one or more cells 1020. In some embodiments, the input port 1060 may comprise a microUSB-type port. In some embodiments, the input port 1060 may not be present, thus a user would have no ability to recharge the one or more cells 1020 via the power input/output module 1040. In some embodiments, the functionality of the output port 1050 and the input port 1060 can be combined into a single port, capable of passing power in both directions through the power input/output module 1040. Thus, a user may charge or discharge the one or more cells using a single connection port.

The outer casing may comprise a cap 1070. The cap 1070 may be disposed on the end of the outer casing which does not house the output port 1050 and the input port 1060. The cap 1070 may advantageously be removable. The cap 1070 may be removably attached to the outer casing 1010. In some embodiments, the cap 1070 may be threaded, snap-fit, friction fit, or otherwise removably attached to the outer casing 1010.

Upon removal of the cap 1070, access may be obtained to the one or more cells 1020 within the outer casing 1010 without interference from the circuitry of the cell connector 1030 and the power input/output module 1040. In some embodiments, the one or more cells 1020 may be removable from the outer casing 1010 through the opening in the outer casing 1010 revealed upon removal of the cap 1070. The other components housed within the outer casing, i.e., the cell connector 1030, the power input/output module 1040, etc., may be retained in place by connection to the internal surfaces of the outer casing 1010, such that they are not easily removable from within the outer casing 1010. In some embodiments, the one or more cells are loaded into a cell tray or cartridge (not shown), which holds the one or more cells 1040 in their proper configuration within the outer casing 1010, and slides in and out of the outer casing 1010, allowing for easy removal and/or insertion of all of the one or more cells 1020 at once. By allowing removal of the one or more cells 1020 via the opening of the cap 1070, spent, discharged, or used cells may be replaced with new, fresh, or charged cells, and the rechargeable power unit 1000 may be quickly returned to use, without having to wait while charging the cells 1020 via the input port 1060.

There may be requirements imposed by regulatory agencies which require restricting access to cells having specific battery chemistries. For example, a regulatory agency may require a manufacturer to restrict access to Li-ion type battery cells. To restrict access in this fashion, the cap 1070 may have a security feature which prevents a user from easily removing the cap 1070. For example, the outer casing 1010 may comprise an outer sheath which is tightly wrapped, shrink wrapped, or otherwise attached to the outer casing 1010 which extends over the removable cap 1070. The outer sheath may extend over the cap 1070 such that the cap cannot be removed without cutting, breaking, destroying, or otherwise altering or removing the outer sheath. In some embodiments, the cap 1070 may be threaded onto the outer casing and tightened securely so that the cap 1070 is torqued greater than “finger-tight,” so a tool is required to remove cap 1070. By using a tool interface (not shown) which requires a specialized, proprietary, or otherwise uncommon tool for removal of the cap 1070, the access restriction requirement may be met.

The rechargeable power unit 1000 may be configured for use in a battery vending or exchange machine. To facilitate receipt of the rechargeable power unit 1000 in the battery vending or exchange machine, the outer casing 1010 may have an orientation feature 1080. The orientation feature 1080 may be a notch, indentation, depression, concavity, convexity, an alignment marking, or other similar feature which may be recognized by the battery vending or exchange machine.

For example, a user may desire to exchange a spent rechargeable power unit 1000, but the user cannot remove the cap 1070 due to access restrictions. The user may insert the rechargeable power unit 1000 into a test port or receiving port on a battery vending or exchange machine. Upon receipt the battery vending or exchange machine may desirably test the state of charge or health of the rechargeable power unit 1000. The battery vending or exchange machine may comprise a connector configured to be inserted into the output port 1050 or the input port 1060, such as a USB or microUSB connector. In order to efficiently ensure the rechargeable power unit 1000 is oriented to make a connection with the connector of the battery vending or exchange machine, the orientation feature 1080 is used. Where the orientation feature 1080 is a notch, the notch 1080 may align with a corresponding feature, such as a tab, or other mechanical alignment feature within the test or receiving port. The user may be unable to insert the rechargeable power unit 1000 except in the orientation where the orientation feature 1080 aligns with the corresponding feature in the test or receiving port.

In some embodiments, the orientation feature 1080 may be a computer readable marking or similar feature capable of being recognized by the identification apparatus within the test or receiving port. The test or receiving port may be configured to rotate the rechargeable power unit 1000 to align the output port 1050 and/or the input port 1060 with the test connection within the battery vending or exchange machine. The orientation feature 1080 may be one of the many battery identifiers described elsewhere herein, e.g., barcodes, QR codes, RFID, and the like, such that it serves a dual purpose for both orientation and identification. The orientation feature 1080 may be used to track and/or identify the rechargeable power unit 1000 as described elsewhere herein.

Once the test connection is inserted into either the output port 1050, the input port 1060, or both, the battery vending or exchange machine may conduct a diagnostic check of the rechargeable power unit 1000. The battery vending or exchange machine may read the internal memory of the power input/output module 1040 wherein the battery charge/discharge information is stored. The stored battery charge/discharge information may be compared to pre-defined parameters to gauge the health of the one or more cells 1020. For example, the pre-determined parameters may relate to the number of charge/discharge cycles, the total amp-hours charged or discharged, or any other battery feature. If the number of charge/discharge cycles, total current charged or discharged, or any other stored battery information exceeds a pre-determined threshold, the rechargeable power unit 1000 may be flagged for replacement of the one or more cells 1020. If the stored battery information is within the normal parameters, the rechargeable power unit 1000 may be transported to a recharging facility, port, connection, or charging hub where the one or more cells are recharged. The recharging of the battery power unit 1000 may advantageously be part of a two-way exchange procedure, where a fresh battery power unit 1000 is vended, sent, shipped, or otherwise provided to a user, and the spent battery power unit 1000 is recharged and readied for reuse by the same or another user.

The test connection of the battery vending or exchange machine may perform a diagnostic check to determine the health of the one or more cells 1020 within the rechargeable power unit 1000. The test connection may measure output voltage and/or current at the output port 1050. The test connection may be instructed to conduct a test discharge and track voltage and current during the test discharge. For example, a loading current of 2 A may be briefly applied (as in a pulse) to the one or more cells 1020 via the input port 1060 while voltage is measured. During application of the current, an excessively low (possibly due to high internal impedance or resistance of the cell) would indicate that a cell 1020 is aged, bad, or malfunctioning. If this occurs, the battery vending or exchange machine may flag the rechargeable power unit 1000 for replacement of the one or more cells 1020. The testing method described above is exemplary only. A persons of skill in the art will understand that many different testing and/or diagnostic methods may be used without departing from the scope of the present disclosure. In some embodiments, the output port 150 and/or the input port 1060 can be used, either alone, or in combination, for testing and diagnostic purposes of the rechargeable power unit 1000.

In some embodiments, when the rechargeable power unit 1000 is inserted into the test or receiving port on the battery vending or exchange machine, the test connection made with the rechargeable power unit 1000 may read the subscriber information, serial number, or other data stored in the internal memory of the power input/output module 1040. In some embodiments, the battery vending or exchange machine may automatically recognize the account of the subscriber based on the stored subscriber information, and may automatically credit, debit, the subscriber's account, vend a fresh rechargeable power unit 1000, or take other action as desired.

The technology is operational with numerous other general purpose or special purpose computing system environments or configurations. Examples of well-known computing systems, environments, and/or configurations that may be suitable for use with the invention include, but are not limited to, personal computers, server computers, hand-held or laptop devices, multiprocessor systems, processor-based systems, programmable consumer electronics, network PCs, minicomputers, mainframe computers, distributed computing environments that include any of the above systems or devices, and the like.

As used herein, instructions refer to computer-implemented steps for processing information in the system. Instructions can be implemented in software, firmware or hardware and include any type of programmed step undertaken by components of the system.

A processor may be any conventional general purpose single- or multi-chip processor such as a Pentium® processor, a Pentium® Pro processor, a 8051 processor, a MIPS® processor, a Power PC® processor, or an Alpha® processor. In addition, the processor may be any conventional special purpose processor such as a digital signal processor or a graphics processor. The processor typically has conventional address lines, conventional data lines, and one or more conventional control lines.

The system is comprised of various modules as discussed in detail. As can be appreciated by one of ordinary skill in the art, each of the modules comprises various sub-routines, procedures, definitional statements and macros. Each of the modules are typically separately compiled and linked into a single executable program. Therefore, the description of each of the modules is used for convenience to describe the functionality of the preferred system. Thus, the processes that are undergone by each of the modules may be arbitrarily redistributed to one of the other modules, combined together in a single module, or made available in, for example, a shareable dynamic link library.

The system may be used in connection with various operating systems such as Linux®, UNIX® or Microsoft Windows®.

The system may be written in any conventional programming language such as C, C++, BASIC, Pascal, or Java, and ran under a conventional operating system. C, C++, BASIC, Pascal, Java, and FORTRAN are industry standard programming languages for which many commercial compilers can be used to create executable code. The system may also be written using interpreted languages such as Perl, Python or Ruby.

Those of skill will further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In one or more example embodiments, the functions and methods described may be implemented in hardware, software, or firmware executed on a processor, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

The foregoing description details certain embodiments of the systems, devices, and methods disclosed herein. It will be appreciated, however, that no matter how detailed the foregoing appears in text, the systems, devices, and methods can be practiced in many ways. As is also stated above, it should be noted that the use of particular terminology when describing certain features or aspects of the invention should not be taken to imply that the terminology is being re-defined herein to be restricted to including any specific characteristics of the features or aspects of the technology with which that terminology is associated.

It will be appreciated by those skilled in the art that various modifications and changes may be made without departing from the scope of the described technology. Such modifications and changes are intended to fall within the scope of the embodiments. It will also be appreciated by those of skill in the art that parts included in one embodiment are interchangeable with other embodiments; one or more parts from a depicted embodiment can be included with other depicted embodiments in any combination. For example, any of the various components described herein and/or depicted in the Figures may be combined, interchanged or excluded from other embodiments.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

While various aspects and embodiments have been disclosed herein, other aspects and embodiments will be apparent to those skilled in the art. The various aspects and embodiments disclosed herein are for purposes of illustration and are not intended to be limiting.

What is claimed is:

1. A rechargeable power unit comprising:
one or more battery cells;
a power module electrically connected to the one or more battery cells;
an output port electrically connected to the power module, the output port configured to engage a connector, the power module configured to provide power from the one or more battery cells to the connector;
a casing enclosing the one or more battery cells; and
a cap removably attached to the casing, wherein, when the cap is removed, an opening is created in the casing, and wherein the battery cells are removable from the casing via the opening.

2. The rechargeable power unit of claim 1, wherein the power module comprises current and/or voltage transformation circuitry.

3. The rechargeable power unit of claim 2, wherein the power module further comprises internal memory configured to store information relating to the state of charge of the battery.

4. The rechargeable power unit of claim 3, wherein the information relating to the state of charge comprises the number of charge/discharge cycles, the total ampere-hours charged, or the total number of ampere-hours discharged.

5. The rechargeable power unit of claim 3, wherein the internal memory of the power module is further configured to store a unique identifier.

6. The rechargeable power unit of claim 5, wherein the unique identifier is associated with a subscriber or purchaser of the rechargeable power unit.

7. The rechargeable power unit of claim 1, wherein the casing and the cap are covered in a sheath such that the cap is not removable without affecting the integrity of the sheath.

8. The rechargeable power unit of claim 1, wherein the cap is threadably engageable with the casing, which requires use of a tool to unthread and remove the cap.

9. The rechargeable power unit of claim 8, wherein the tool feature requires use of a proprietary tool feature.

10. The rechargeable power unit of claim 1, further comprising an orientation feature which is useable to determine the orientation of the rechargeable power unit within a battery vending or exchange machine.

11. The rechargeable power unit of claim 10, wherein the orientation feature comprises a notch or indentation in the casing.

12. The rechargeable power unit of claim 10, wherein the orientation feature comprises a unique computer-readable identifier useable to identify the rechargeable power unit.
